(19) United States
(12) Patent Application Publication
(10) Pub. No.: US 2026/0036906 A1
(43) Pub. Date: Feb. 5, 2026

(54) RESIST TOPCOAT COMPOSITION AND METHOD OF FORMING PATTERNS USING THE COMPOSITION

(71) Applicant: SAMSUNG SDI CO., LTD., Suwon-si (KR)

(72) Inventors: Ran NAMGUNG, Suwon-si (KR); Hyeon PARK, Suwon-si (KR); Kyoungjin HA, Suwon-si (KR); Daeseok SONG, Suwon-si (KR); Minsoo KIM, Suwon-si (KR)

(21) Appl. No.: 19/175,813

(22) Filed: Apr. 10, 2025

(30) Foreign Application Priority Data
Jul. 31, 2024 (KR) 10-2024-0102083

(51) Int. Cl. G03F 7/11; G03F 7/09; G03F 7/16; H01L 21/027

(52) U.S. Cl. CPC G03F 7/11; G03F 7/094; G03F 7/168; H01L 21/0274

(57) ABSTRACT

A resist topcoat composition and a method of forming patterns using the resist topcoat composition are provided. The resist topcoat composition including a polymer including a first structural unit represented by Chemical Formula M-1 and a second structural unit represented by Chemical Formula 2; and a solvent. Details about the Chemical Formulas are as described in the specification.

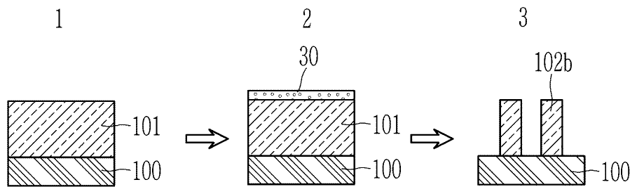

### CROSS-REFERENCE TO RELATED APPLICATION

The present application claims priority to and the benefit of Korean Patent Application No. 10-2024-0102083, filed on Jul. 31, 2024, in the Korean Intellectual Property Office, the entire content of which is incorporated herein by reference.

### BACKGROUND

### 1. Field

This disclosure relates to a resist topcoat composition, and a method of forming a pattern using the same.

### 2. Description of the Related Art

Recently, the semiconductor industry has advanced to ultrafine technique capable of creating patterns with dimensions from several to several tens of nanometers. Such ultrafine techniques rely on (e.g., essentially rely on) effective photolithographic processes.

Related art photolithographic processes involve forming a material layer on a semiconductor substrate, coating a photoresist layer thereon, exposing and developing the photoresist layer to form a photoresist pattern, and then etching the material layer using the photoresist pattern as a mask.

As photolithography processes evolve, the degree of pattern integration increases, necessitating the development of materials and technologies to address various issues arising in this process.

For example, if (e.g., when) extreme ultraviolet (EUV) is irradiated to (onto) the photoresist, the high energy per photon may cause regions of random or undesirable irradiation, known as photon shot noise. Additionally, differences in EUV absorption between the top and bottom of the photoresist can lead to pattern dispersion deterioration, such as increased roughness (LER: line edge roughness, LWR: line width roughness) and in-point uniformity (IPU) of the patterns. To mitigate this pattern dispersion deterioration, further technological development is desired or required.

### SUMMARY

An aspect according to one or more embodiments is directed toward a resist topcoat composition that not only prevents or reduces pattern degradation and dispersion, but also improves sensitivity.

An aspect according to one or more embodiments is directed toward a method of forming patterns using the resist topcoat composition.

Additional aspects will be set forth in part in the description which follows and, in part, will be apparent from the description, or may be learned by practice of the presented embodiments of the disclosure.

According to some embodiments, a resist topcoat composition includes a polymer including a first structural unit represented by Chemical Formula M-1 and a second structural unit represented by Chemical Formula 2; and a solvent.

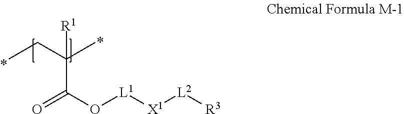

In Chemical Formula M-1,
R¹ may be hydrogen or a substituted or unsubstituted C1 to C10 alkyl group,
L¹ and L² may each independently be a single bond, a substituted or

unsubstituted C1 to C10 alkylene group, and/or a (e.g., any suitable) combination thereof,
X¹ may be a single bond, —O—, —S—, —S(═O)—, —S(═O)₂—, —C(═O)—, —C(═O)O—, —OC(═O)—, —OC(—O)O—, —NR^{a}—(wherein, R^{a} may be hydrogen, deuterium, or a substituted or unsubstituted C1 to C10 alkyl group), and/or a (e.g., any suitable) combination thereof,
R⁴ may be hydrogen, fluorine, a hydroxyl group, a substituted or unsubstituted C1 to C20 alkyl group, and/or a (e.g., any suitable) combination thereof,
at least one of R⁴, L¹, or L² includes fluorine and a hydroxyl group, and
* is a linking point;

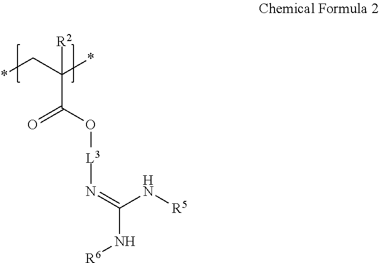

wherein, in Chemical Formula 2,
R² may be hydrogen or a substituted or unsubstituted C1 to C10 alkyl group,
L³ may be a single bond, a substituted or unsubstituted C1 to C10 alkylene group, and/or a (e.g., any suitable) combination thereof,
R⁵ and R⁶ may each independently be hydrogen, a substituted or unsubstituted C1 to C10 alkyl group, or —C(═O)OR⁷ (wherein, R⁷ is a substituted or unsubstituted C1 to C10 alkyl group),
at least one of R⁵ or R⁶ is a substituted or unsubstituted C1 to C10 alkyl group, or —C(═O)OR⁷, and
* is a linking point.

According to some embodiments, a method of forming patterns includes coating and heating a photoresist composition on a substrate to form a photoresist layer, coating and heating the aforementioned resist topcoat composition on the photoresist layer to form a topcoat, and exposing and developing the topcoat and the photoresist layer to form a resist pattern.

According to some embodiments, the resist topcoat composition improves the profile of an upper portion of a photoresist pattern by capturing (or quenching) an acid on the surface of a photoresist if (e.g., when) exposed to EUV, thereby preventing or reducing deterioration of pattern dispersion such as LWR (line width roughness) and/or IPU (In-Point Uniformity) of the pattern and thus being advantageously or desirably used for forming a fine photoresist pattern.

### BRIEF DESCRIPTION OF THE DRAWING

The above and other aspects, features, and enhancements of certain embodiments of the disclosure will be more apparent from the following description taken in conjunction with the accompanying drawing, in which: the drawing is a schematic view for explaining a method of forming patterns using a resist topcoat composition according to one or more embodiments.

### DETAILED DESCRIPTION

Hereinafter, embodiments will be described in more detail so that those skilled in the art can easily implement the present disclosure. However, this disclosure may be embodied in many different forms and is not to be construed as limited to the example embodiments set forth herein.

In the drawings, the thickness of layers, films, panels, regions, and/or the like, may be exaggerated for clarity and like reference numerals designate like elements throughout, and duplicative descriptions thereof may not be provided in the specification. It will be understood that if (e.g., when) an element such as a layer, film, region, or substrate is referred to as being “on” another element, it can be directly on the other element or intervening elements may also be present. In contrast, if (e.g., when) an element is referred to as being “directly on” another element, there are no intervening elements present.

As used herein, if (e.g., when) a definition is not otherwise provided, the term “substituted” refers to replacement of a hydrogen atom of a compound (e.g., molecule) by a substituent selected from among a halogen atom (F, Br, Cl, or I), a hydroxyl group, a thiol group, a nitro group, a cyano group, an amino group, a substituted or unsubstituted C1 to C30 amine group, an azido group, an amidino group, a hydrazino group, a hydrazono group, a carbonyl group, a carbamyl group, a thiol group, an ester group, a carboxyl group or a salt thereof, a sulfonic acid group or a salt thereof, a phosphoric acid group or a salt thereof, a vinyl group, a C1 to C20 alkyl group, a C2 to C20 alkenyl group, a C2 to C20 alkynyl group, a C6 to C30 aryl group, a C7 to C30 arylalkyl group, a C6 to C30 allyl group, a C1 to C30 alkoxy group, a C1 to C30 sulfide group, a C1 to C20 heteroalkyl group, a C3 to C20 heteroarylalkyl group, a C3 to C30 cycloalkyl group, a C3 to C15 cycloalkenyl group, a C6 to C15 cycloalkynyl group, a C3 to C30 heterocycloalkyl group, and/or a (e.g., any suitable) combination thereof.

As used herein, if (e.g., when) a definition is not otherwise provided, the term “alkyl group” refers to a linear or branched aliphatic hydrocarbon group. The alkyl group may be a “saturated alkyl group” without any double bond or triple bond.

The alkyl group may be a C1 to C8 alkyl group. For example, the alkyl group may be a C1 to C10 alkyl group or a C1 to C6 alkyl group. For example, the C1 to C5 alkyl group refers to that the alkyl chain contains 1 to 5 carbon atoms and is selected from among a methyl group, an ethyl group, a propyl group, an iso-propyl group, an n-butyl group, an iso-butyl group, a sec-butyl group, and a tert-butyl group.

In some embodiments, the alkyl group refers to specific examples that are a methyl group, an ethyl group, a propyl group, an isopropyl group, a butyl group, an isobutyl group, a tert-butyl group, a pentyl group, a hexyl group, and/or the like.

In chemical formulas described herein, t-Bu refers to a tert-butyl group.

As used herein, if (e.g., when) a definition is not otherwise provided, the term “cycloalkyl group” refers to a monovalent cyclic aliphatic hydrocarbon group.

The cycloalkyl group may be a C3 to C10 cycloalkyl group, for example, a C3 to C8 cycloalkyl group, a C3 to C7 cycloalkyl group, or a C3 to C6 cycloalkyl group. For example, the cycloalkyl group may be a cyclopropyl group, a cyclobutyl group, a cyclopentyl group, or a cyclohexyl group, but the present disclosure is not limited thereto.

In some embodiments, the cycloalkyl group refers to a cyclopropyl group, a cyclobutyl group, a cyclopentyl group, a cyclohexyl group, and/or the like.

As used herein, unless otherwise defined, the term “alkenyl group” refers to an aliphatic unsaturated alkenyl group including at least one double bond as a linear or branched aliphatic hydrocarbon group.

As used herein, unless otherwise defined, the term “alkynyl group” refers to an aliphatic unsaturated alkynyl group including at least one triple bond as a linear or branched aliphatic hydrocarbon group.

As used herein, the term “aryl group” refers to a substituent in which all atoms in the cyclic substituent (i.e., all ring-forming atoms) have a p-orbital and these p-orbitals are conjugated and may include a monocyclic or fused ring polycyclic (i.e., rings sharing adjacent pairs of carbon atoms) functional group.

As used herein, if (e.g., when) a definition is not otherwise provided, the term “hetero” refers to one including 1 to 3 heteroatoms selected from among N, O, S, Se, and P.

In the present disclosure, if (e.g., when) a definition is not otherwise provided, the term “heterocycloalkyl group” refers to a cycloalkyl group containing at least one hetero atom selected from among N, O, S, P, and Si.

In the present disclosure, the term “heteroaryl group” refers to an aryl group including at least one hetero atom selected from among N, O, S, P, and Si. Two or more heteroaryl groups may be linked by a sigma bond directly, or if (e.g., when) the heteroaryl group includes two or more rings, the two or more rings may be fused. If (e.g., when) the heteroaryl group is a fused ring, each ring may include 1 to 3 hetero atoms.

Unless otherwise specified in the present specification, the weight average molecular weight is measured by dissolving a sample (e.g., a powder sample) in tetrahydrofuran (THF) and then obtaining the weight average molecular weight using 1200 series Gel Permeation Chromatography (GPC) of Agilent Technologies (column is Shodex Company LF-804, standard sample is Shodex company polystyrene).

In addition, unless otherwise defined in the specification, “*” indicates a linking point of a structural unit or a moiety (compound moiety) of a compound.

Hereinafter, a photoresist topcoat composition according to some example embodiments is described.

The present disclosure relates to a photoresist topcoat composition which improves the sensitivity of photoresist during a fine pattern formation process of photolithography using high energy rays such as EUV (Extreme ultraviolet; wavelength 13.5 nm) and at the same time selectively reduces the concentration of acid in an upper portion of the photoresist, thereby improving the In-Point Uniformity (IPU) of a contact hole (C/H) pattern, the LER (line edge roughness)/LWR (line width roughness) of a line and space (L/S) pattern, and the IPU of a pillar pattern, and a method for forming a photoresist pattern using such a topcoat (e.g., formed from the photoresist topcoat composition).

The resist topcoat composition according to one or more embodiments includes a polymer including a first structural unit represented by Chemical Formula M-1 and a second structural unit represented by Chemical Formula 2; and a solvent.

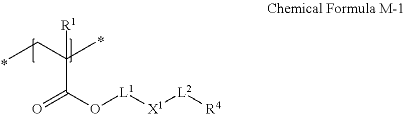

In Chemical Formula M-1,
R¹ may be hydrogen or a substituted or unsubstituted C1 to C10 alkyl group,
L¹ and L² may each independently be a single bond, a substituted or unsubstituted C1 to C10 alkylene group, and/or a (e.g., any suitable) combination thereof,
X¹ may be a single bond, —O—, —S—, —S(═O)—, —S(═O)₂—, —C(═O)—, —C(═O)O—, —OC(═O)—, —OC(═O)O—, —NR^{a}—(wherein, R^{a} may be hydrogen, deuterium, or a substituted or unsubstituted C1 to C10 alkyl group), and/or a (e.g., any suitable) combination thereof,
R⁴ may be hydrogen, fluorine, a hydroxyl group, a substituted or unsubstituted C1 to C20 alkyl group, and/or a (e.g., any suitable) combination thereof,
at least one of R⁴, L¹, and L² includes fluorine and a hydroxyl group, and
* is a linking point;

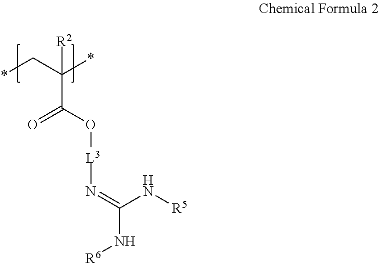

wherein, in Chemical Formula 2,
R² may be hydrogen or a substituted or unsubstituted C1 to C10 alkyl group,
L³ may be a single bond, a substituted or unsubstituted C1 to C10 alkylene group, and/or a (e.g., any suitable) combination thereof,
R⁵ and R⁶ may each independently be hydrogen, a substituted or unsubstituted C1 to C10 alkyl group, or —C(═O)OR⁷ (wherein, R⁷ may be a substituted or unsubstituted C1 to C10 alkyl group),
at least one of R⁵ and R⁶ is a substituted or unsubstituted C1 to C10 alkyl group, or —C(═O)OR⁷, and
* is a linking point.

If (e.g., when) patterning a photoresist by exposing with EUV, the high energy of EUV photons may cause photon shot noise, which may result in deterioration of pattern dispersion such as pattern roughness (LER, LWR) or IPU.

The photoresist topcoat composition according to some example embodiments can suppress or reduce pattern dispersion deterioration by reducing the concentration of acid generated in a photoresist layer by introducing a structural unit including a guanidine functional group into a polymer, and can also improve sensitivity by promoting dissolution in a developer.

In addition, the polymer can protect the photoresist by including structural units including fluoro and hydroxyl groups that have little (low) reactivity with the photoresist and can be easily dissolved in a solvent. Because it can be easily dissolved in a solvent, it can also be easily removed, thereby minimizing or reducing the influence on the photoresist.

For example, the photoresist topcoat composition according to the present disclosure can be applied on top of a photoresist layer to significantly improve the LER/LWR of an L/S pattern, the IPU of a C/H pattern, and the IPU of a pillar pattern, as well as also improving the sensitivity.

For example, the first structural unit may be represented by Chemical Formula 1.

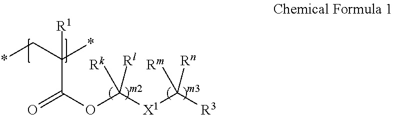

In Chemical Formula 1,
R¹ may be hydrogen or a substituted or unsubstituted C1 to C10 alkyl group,
R^{k}, R^{l}, R^{m}, and Rⁿ may each independently be hydrogen, fluorine, a hydroxyl group, a substituted or unsubstituted C1 to C20 alkyl group, and/or a (e.g., any suitable) combination thereof,
m2 and m3 may each independently be an integer selected from 1 to 10,
X¹ may be a single bond, —O—, —S—, —S(═O)—, —S(═O)₂—, —C(═O)—, —C(═O)O—, —OC(═O)—,—OC(═O)O—, —NR^{a}—(wherein, R^{a} may be hydrogen, deuterium, or a substituted or unsubstituted C1 to C10 alkyl group), and/or a (e.g., any suitable) combination thereof,
R⁴ may be hydrogen, fluorine, a hydroxyl group, a substituted or unsubstituted C1 to C20 alkyl group, and/or a (e.g., any suitable) combination thereof, and
at least one of R^{k}, R^{l}, R^{m}, Rⁿ, and R⁴ includes fluorine and a hydroxyl group.

In Chemical Formula 1, if (e.g., when) m2 is 2 or more, each R^{k} may be the same or different from each other.

In Chemical Formula 1, if (e.g., when) m2 is 2 or more, each R^{l} may be the same or different from each other.

In Chemical Formula 1, if (e.g., when) m3 is 2 or more, each R^{m} may be the same or different from each other.

In Chemical Formula 1, if (e.g., when) m3 is 2 or more, each Rⁿ may be the same or different from each other.

In Chemical Formula 1, the expression that at least one of R^{k}, R^{l}, R^{m}, Rⁿ and R⁴ includes fluorine and a hydroxyl group may include cases where,
at least one of R^{k}, R^{l}, R^{m}, Rⁿ, and R⁴ each independently includes fluorine and at least one of the others each independently includes a hydroxyl group, or
at least one of R^{k}, R^{l}, R^{m}, Rⁿ, and R⁴ each independently includes a C1 to C10 alkyl group substituted with one or more fluorine and at least one of the others each independently includes a C1 to C10 alkyl group substituted with one or more hydroxyl groups, or
at least one of R^{k}, R^{l}, R^{m}, Rⁿ, and R⁴ each independently includes one or more hydroxyl groups and at least one of the others each independently includes one or more C1 to C10 alkyl groups substituted with fluorine, or
at least one of R^{k}, R^{l}, R^{m}, Rⁿ, and R⁴ each independently includes a C1 to C5 alkyl group substituted with one or more hydroxyl groups and at least one of the others each independently includes one or more C1 to C5 fluoroalkyl groups, or
at least one of R^{k}, R^{l}, R^{m}, Rⁿ, and R⁴ is fluorine, and at least one of the others is a hydroxyl group, or
at least one of R^{k}, R^{l}, R^{m}, Rⁿ, and R⁴ is fluorine, and at least one of the others includes a C1 to C10 alkyl group substituted with one or more hydroxyl groups, or
at least one of R^{k}, R^{l}, R^{m}, Rⁿ, and R⁴ is a hydroxyl group, and at least one of the others includes a C1 to C10 alkyl group substituted with one or more fluorine atoms, or
at least one of R^{k}, R^{l}, R^{m}, Rⁿ, and R⁴ is a C1 to C20 alkyl group substituted with one or more fluorine, and at least one of the others is a C1 to C20 alkyl group substituted with one or more hydroxyl groups.
For example, R¹ may be hydrogen or a methyl group,
X¹ may be a single bond, —O—, or —NR^{a}—(wherein, R^{a} may be hydrogen, deuterium, or a substituted or unsubstituted C1 to C10 alkyl group), and
R⁴ may be fluorine, a hydroxyl group, a C1 to C10 alkyl group substituted with at least one fluorine, or a C1 to C10 alkyl group substituted with at least one hydroxyl group.

As an example, in Chemical Formula 1, at least one of R^{m}, Rⁿ and R⁴ may include a fluorine and a hydroxyl group.

As an example, at least one of Rm and Rn in Chemical Formula 1 may be fluorine or a C1 to C10 alkyl group substituted with at least one fluorine, and R⁴ may be a hydroxyl group or a C1 to C10 alkyl group substituted with at least one hydroxyl group.

As an example, in Chemical Formula 1, at least one of Rm and Rn may be fluorine or a C1 to C10 alkyl group substituted with at least one fluorine, and R⁴ may be a hydroxyl group or a C1 to C10 alkyl group substituted with at least one hydroxyl group.

As an example, in Chemical Formula 1, R^{m} may be a hydroxyl group or a C1 to C10 alkyl group substituted with at least one hydroxyl group, Rn may be fluorine or a C1 to C10 alkyl group substituted with at least one fluorine, and R⁴ may be a hydroxyl group, fluorine, or a C1 to C10 alkyl group substituted with at least one of fluorine and hydroxyl groups.

As an example, in Chemical Formula 1, at least one of R^{m} and Rⁿ may be fluorine or a C1 to C10 alkyl group substituted with at least one fluorine, and R⁴ may be a hydroxyl group or a C1 to C5 alkyl group substituted with at least one of a hydroxyl group and a C1 to C5 fluoroalkyl group.

For example, the first structural unit may be any one selected from among Group I.

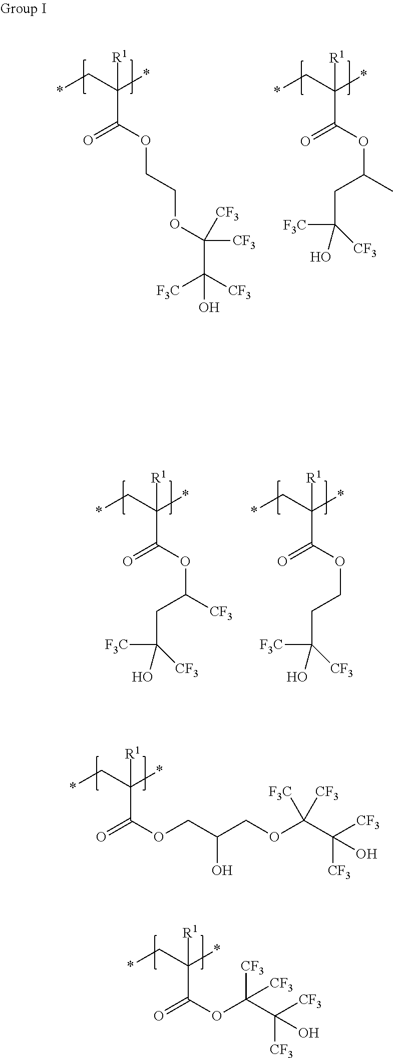

In Group I,
R¹ may be each independently hydrogen or a methyl group, and * is a linking point.

For example, at least one of R⁵ and R⁶ may be a substituted C1 to C10 alkyl group, or —C(═O)OR⁷ (wherein R⁷ may be a substituted C1 to C10 alkyl group).

In some embodiments, at least one of R⁵ and R⁶ may be a substituted methyl group, a substituted ethyl group, a substituted propyl group, a substituted butyl group, a substituted pentyl group, a substituted hexyl group, or —C(═O)OR⁷ (wherein, R⁷ may be a substituted methyl group, a substituted ethyl group, a substituted propyl group, a substituted butyl group, a substituted pentyl group, or a substituted hexyl group).

For example, at least one of R⁵ and R⁶ may be a substituted or unsubstituted tert-butyl group, or —C(═O)OR⁷ (wherein R⁷ may be a substituted or unsubstituted tert-butyl group).

In some example embodiments, the second structural unit may be derived from a compound of Chemical Formula be.

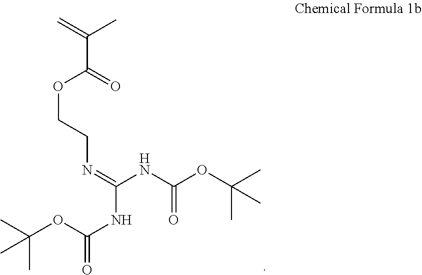

The polymer may further include an additional structural unit represented by Chemical Formula M-2.

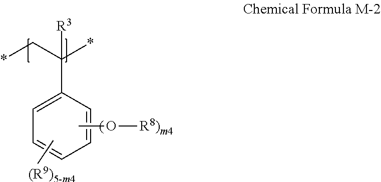

In Chemical Formula M-2,
R³ may be hydrogen or a substituted or unsubstituted C1 to C10 alkyl group,
R⁸ may be hydrogen, or —C(═O)R^{d},

R^{d} may be a substituted or unsubstituted C1 to C10 alkyl group,

R⁹ may be hydrogen, a halogen, a hydroxyl group, a substituted or unsubstituted C1 to C10 alkyl group, and/or a (e.g., any suitable) combination thereof,
m4 may be an integer selected from 1 to 4, and
* is a linking point.

In Chemical Formula M-2, if (e.g., when) m4 is 2 or more, each O—R⁸ may be the same or different from each other.

In Chemical Formula M-2, if (e.g., when) 5-m4 is 2 or more, each R⁹ may be the same or different.

As an example, the additional structural unit may be represented by any one of Chemical Formula 4-1 to Chemical Formula 4-4.

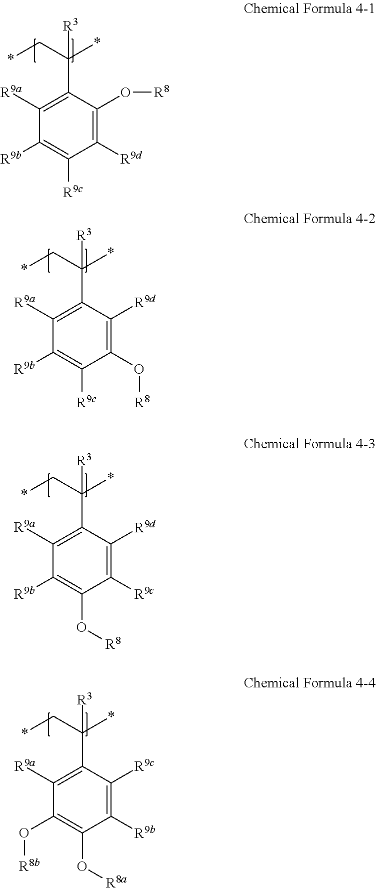

In Chemical Formula 4-1 to Chemical Formula 4-4,
R³ may be hydrogen or a methyl group,
R⁸, R^{8a}, and R^{8b} may each independently be hydrogen, or —C(═O)R^{d},
R^{d} may be a substituted or unsubstituted C1 to C5 alkyl group,
R^{9a}, R^{9b}, R^{9c}, and R^{9d} may each independently be hydrogen, a halogen, a hydroxyl group, a substituted or unsubstituted C1 to C10 alkyl group, and/or a (e.g., any suitable) combination thereof, and
* is a linking point.

For example, at least one of R⁹s (i.e., at least one of R^{9a}, R^{9b}, R^{9c}, and R^{9d}) may be a halogen.

As an example, at least one of R⁹s (i.e., at least one of R^{9a}, R^{9b}, R^{9c}, and R^{9d}) may be an iodine group.

Sensitivity can be further improved by including an iodine group in the additional structural unit.

For example, the additional structural unit may be any one selected from among the groups listed in Group III.

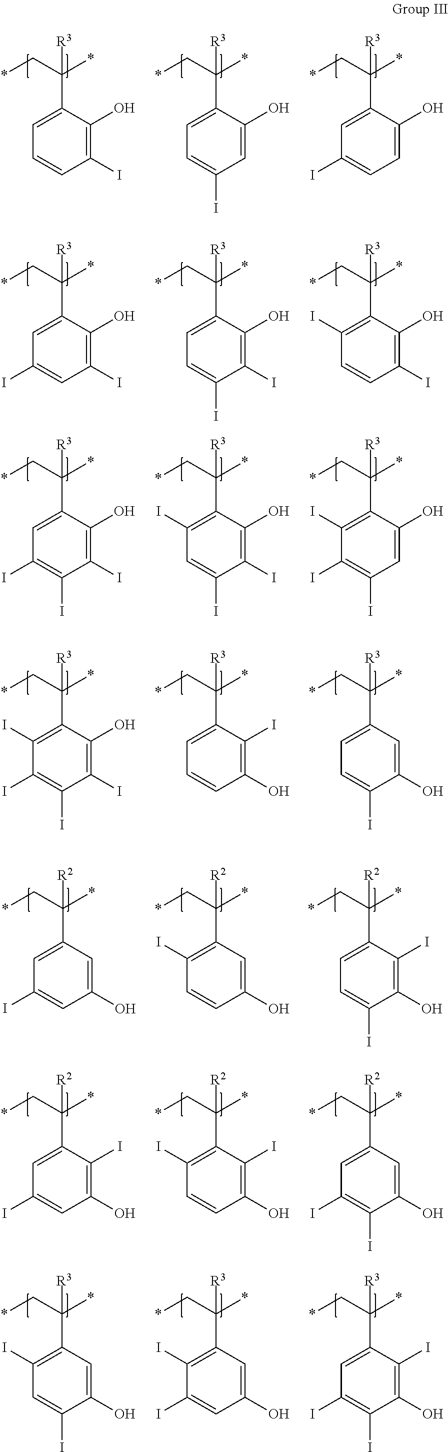

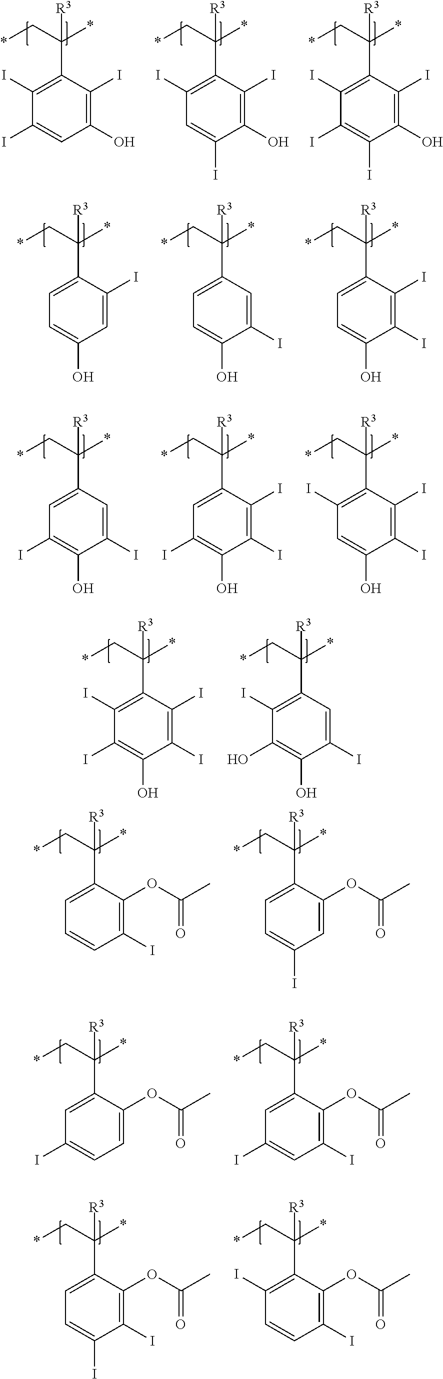

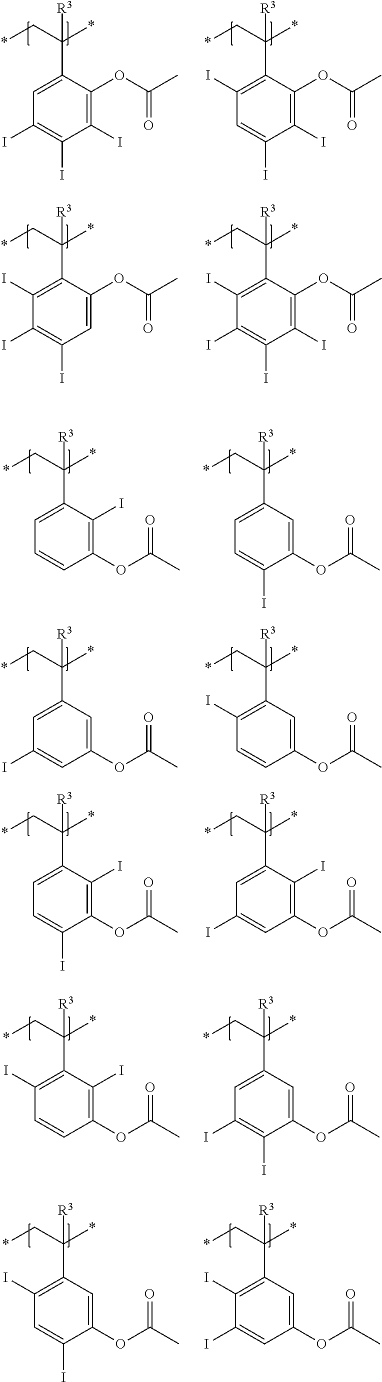

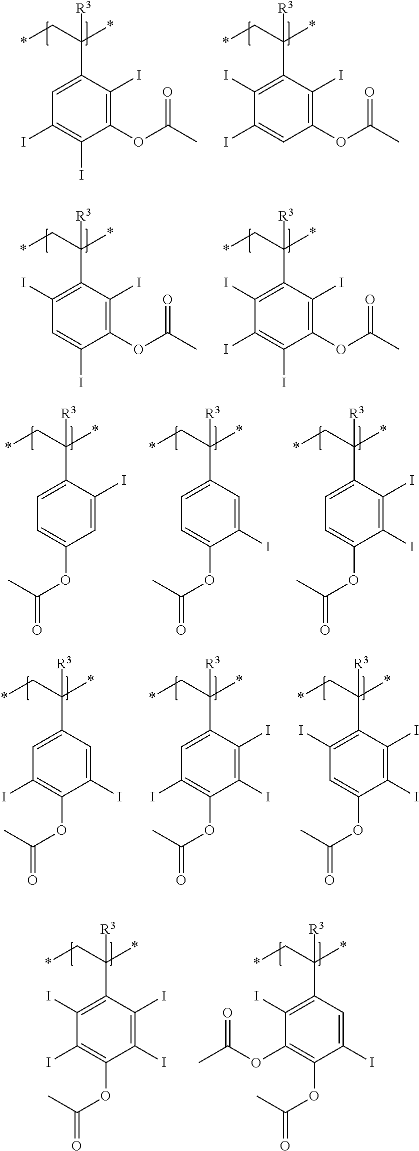

In Group III,
R³ may each independently be hydrogen or a methyl group, and * is a linking point.

The polymer may include about 50 mol % to about 99 mol % of the first structural unit, about 1 mol % to about 50 mol % of the second structural unit, and about 1 mol % to about 40 mol % of the third structural unit.

For example, the polymer may include about 70 mol % to about 99 mol % of the first structural unit and about 1 mol % to about 30 mol % of the second structural unit, or the polymer may include about 70 mol % to about 90 mol % of the first structural unit and about 10 mol % to about 30 mol % of the second structural unit. In an embodiment, the polymer may include about 75 mol % to about 95 mol % of the first structural unit and about 5 mol % to about 25 mol % of the second structural unit.

If the mole ratio of each structural unit included in the polymer is within the above ranges (e.g., 70:30 to 99:1), the solubility in organic solvents is improved and the pattern can be uniformly (e.g., substantially uniformly) coated (e.g., and formed).

The polymer may have a weight average molecular weight (Mw) of about 1,000 g/mol to about 50,000 g/mol. For example, the polymer may have a weight average molecular weight of about 2,000 g/mol to about 30,000 g/mol, about 3,000 g/mol to about 20,000 g/mol, or about 4,000 g/mol to about 10,000 g/mol, but the present disclosure is not limited thereto. If the weight average molecular weight of the polymer is within the above ranges, a carbon content (e.g., amount) and solubility in a solvent of the resist topcoat composition including the copolymer may be improved or optimized.

The polymer may be included in an amount of about 0.1 wt % to about 10 wt % based on a total weight (100 wt %) of the resist topcoat composition.

For example, the polymer may be included in an amount of about 0.1 wt % to about 5 wt %, or about 0.1 wt % to about 3 wt %, based on the total weight of the resist topcoat composition.

Within the above ranges, the resist topcoat may be easily removed.

In one or more embodiments, the polymer may be any one selected from among those listed in Group IV.

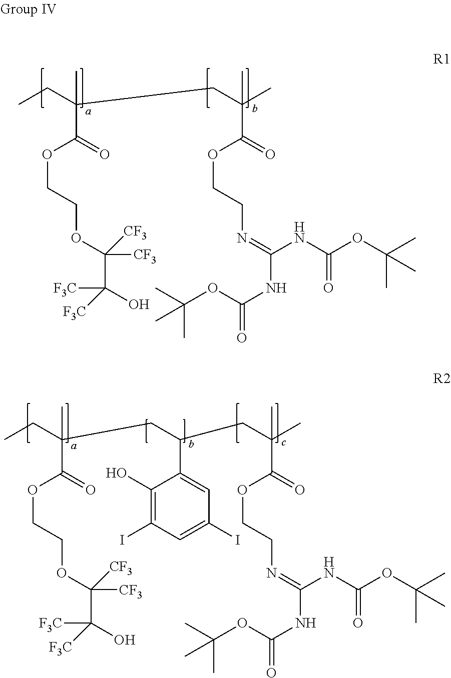

In Group IV, a:b may be about 99:1 to about 70:30, for example, about 90:10 to about 70:30, or about 95:5 to about 75:25.

In some embodiments, the resist topcoat composition may further include at least one other polymer selected from among an epoxy-based resin, a novolac resin, a glycoluril-based resin, and a melamine-based resin, but the present disclosure is not limited thereto.

The resist topcoat composition may further include an additive including a surfactant, a thermal acid generator, a plasticizer, and/or a (e.g., any suitable) combination thereof.

The surfactant may be, for example, an alkylbenzene sulfonic acid salt, an alkyl pyridinium salt, polyethylene glycol, a quaternary ammonium salt, and/or the like, but the present disclosure is not limited thereto.

The thermal acid generator may be, for example, an acid compound such as p-toluene sulfonic acid, trifluoromethanesulfonic acid, pyridinium p-toluene sulfonic acid, salicylic acid, sulfosalicylic acid, citric acid, benzoic acid, hydroxybenzoic acid, naphthalene carboxylic acid and/or benzoin tosylate, 2-nitrobenzyl tosylate, and/or other organic sulfonic acid alkyl esters, but the present disclosure is not limited thereto.

The amount of these additives used can be easily adjusted according to desired or suitable physical properties. In some embodiments, the additives may not be provided (i.e., the resist topcoat composition may not include any of the additives).

The solvent may be an ether-based solvent, and is, for example, represented by Chemical Formula 5.

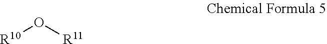

In Chemical Formula 5,
R¹⁰ and R¹¹ may each independently be a substituted or unsubstituted C1 to C20 alkyl group, or a substituted or unsubstituted C3 to C30 cycloalkyl group.

For example, the ether-based solvent may be any one selected from among diisopropyl ether, dipropyl ether, diisoamyl ether, diamyl ether, dibutyl ether, diisobutyl ether, di-sec-butyl ether, dihexyl ether, bis(2-ethylhexyl) ether, didecyl ether, diundecyl ether, didodecyl ether, ditetradecyl ether, hexadecyl ether, butyl methyl ether, butyl ethyl ether, butyl propyl ether, tert-butyl methyl ether, tert-butyl ethyl ether, tert-butylpropyl ether, di-tert-butyl ether, cyclopentylmethyl ether, cyclohexylmethyl ether, cyclopentylethyl ether, cyclohexylethyl ether, cyclopentylpropyl ether, cyclopentyl-2-propyl ether, cyclohexylpropyl ether, cyclohexyl-2-propyl ether, cyclopentylbutyl ether, cyclopentyl-tert-butyl ether, cyclohexylbutyl ether, cyclohexyl-tert-butyl ether, and/or a (e.g., any suitable) combination thereof.

The ether-based solvent may have sufficient solubility or dispersibility for the aforementioned composition.

In one or more embodiments, a method of forming patterns using the aforementioned photoresist topcoat composition may be provided. For example, the manufactured pattern may be a photoresist pattern.

A method of forming patterns according to some example embodiments includes coating and heating a photoresist composition on a substrate to form a photoresist layer, coating and heating the aforementioned photoresist topcoat composition on the photoresist layer to form a topcoat, and exposing and developing the topcoat and the photoresist layer to form a resist pattern.

Hereinafter, a method of forming patterns using the aforementioned photoresist topcoat composition will be described with reference to the drawing. The drawing is a schematic view for explaining a method of forming patterns using a photoresist topcoat composition according to embodiments of the present disclosure.

Referring to the drawing, first, an object 100 to be etched is prepared. An example of the object to be etched may be a thin film formed on a semiconductor substrate. Hereinafter, for ease of description, only the case where the object to be etched is a thin film will be described. The surface of the thin film is cleaned to remove contaminants remaining on the thin film. The thin film may be, for example, a silicon nitride film, a polysilicon film, or a silicon oxide film.

A photoresist composition is coated on the thin film and heated to form a photoresist layer 101 (Step or act 1). Subsequently, the photoresist topcoat composition is coated on the photoresist layer and heated to form a photoresist topcoat 30 (Step or act 2).

The heating may be performed at a temperature of about 80° C. to about 500° C.

Then, the photoresist topcoat and the photoresist layer are exposed to high-energy radiation (e.g., through a patterned mask).

For example, the high-energy radiation that can be used in the exposure process may include light having a high-energy wavelength, such as EUV (Extreme Ultraviolet; wavelength: about 13.5 nm) and/or E-Beam (electron beam).

A post-exposure heat treatment (PEB) is then performed. The post-exposure heat treatment may be performed at a temperature of about 80° C. to about 200° C. By performing the post-exposure heat treatment, the exposed region of the photoresist layer, that is, the region not covered by the patterned mask is changed to a property that is soluble in a developer, so that the exposed region has a different solubility from that of the unexposed region of the photoresist layer.

A photoresist pattern 102b may be formed by dissolving and removing the photoresist layer corresponding to the exposed region and the photoresist topcoat using a developer (Step or act 3).

For example, the developer may be an alkaline developer or a developer containing an organic solvent (hereinafter referred to as an organic-based developer).

As the alkaline developer, a quaternary ammonium salt such as tetramethylammonium hydroxide is usually used, but aqueous alkaline solutions such as inorganic alkalis, primary to tertiary amines, alcohol amines, and/or cyclic amines may also be used.

Moreover, the alkaline developer may contain alcohol and/or surfactant in an appropriate or suitable amount. An alkaline concentration of the alkaline developer may be, for example, about 0.1 mass % to about 20 mass %, and a pH of the alkaline developer may be, for example, about 10 to about 15.

The organic-based developer may be a developer containing at least one organic solvent selected from among (e.g., selected from the group consisting of) ketone solvents, ester solvents, alcohol solvents, amide solvents, ether solvents, and hydrocarbon solvents.

Examples of the ketone solvent may include 1-octanone, 2-octanone, 1-nonanone, 2-nonanone, acetone, 2-heptanone (methyl amyl ketone), 4-heptanone, 1-hexanone, 2-hexanone, diisobutyl ketone, cyclohexanone, methylcyclohexanone, phenylacetone, methyl ethyl ketone, methyl isobutyl ketone, acetylacetone, acetonyl acetone, ionone, diacetonyl alcohol, acetyl carbinol, acetophenone, methyl naphthyl ketone, isophorone, propylene carbonate, and/or the like.

Examples of the ester solvent may include methyl acetate, butyl acetate, ethyl acetate, isopropyl acetate, pentyl acetate, isopentyl acetate, amyl acetate, propylene glycol monomethyl ether acetate, ethylene glycol monoethyl ether acetate, ethylene glycol monobutyl ether acetate, ethylene glycol monoethyl ether acetate, ethyl-3-ethoxypropionate, 3-methoxybutyl acetate, 3-methyl-3-methoxybutyl acetate, methyl formate, ethyl formate, butyl formate, propyl formate, ethyl lactate, butyl lactate, propyl lactate, butyl butanoate, methyl 2-hydroxyisobutyrate, isoamyl acetate, isobutyl isobutyrate, butyl propionate, and/or the like.

Any suitable (e.g., known) alcohol solvents, amide solvents, ether solvents, and hydrocarbon solvents may be used.

In some embodiments, a plurality of said solvents may be mixed, or may be mixed with solvents or water other than the above-described solvents. A moisture content (e.g., amount) as a whole of the developer may be desirably less than about 50 wt %, less than about 20 wt %, or less than about 10 wt %, and in an embodiment, the developer may be substantially free of moisture.

A content (e.g., amount) of the organic solvent may be desirably about 50 wt % to about 100 wt %, about 80 wt % to about 100 wt %, about 90 wt % to about 100 wt %, or about 95 wt % to about 100 wt % based on a total amount (100 wt %) of the organic developer.

In some embodiments, the organic developer may include an appropriate or suitable amount of a suitable surfactant as desired or required.

A content (e.g., amount) of the surfactant may be usually about 0.001 wt % to about 5 wt %, 0.005 wt % to about 2 wt %, or about 0.01 wt % to about 0.5 wt % based on a total amount (100 wt %) of the developer.

In some embodiments, the organic developer may include an inhibitor.

Subsequently, the exposed thin film 100 is etched by applying the photoresist pattern 102b as an etching mask. As a result, the thin film 100 is formed into a thin film pattern.

The thin film may be etched, for example, by dry etching using an etching gas, and the etching gas may be, for example, CHF₃, CF₄, Cl₂, BCl₃, and/or a (e.g., any suitable) mixture thereof.

In the exposure process performed above, the thin film pattern formed using the photoresist pattern 102b that is formed by the exposure process performed using the EUV light source may have a width corresponding to the photoresist pattern 102b. In some embodiments, the photoresist pattern 102b may have a width of about 5 nm to about 100 nm. In some embodiments, the thin film pattern formed by the exposure process performed using an EUV light source may have a width of about 5 nm to about 90 nm, about 5 nm to about 80 nm, about 5 nm to about 70 nm, about 5 nm to about 60 nm, about 5 nm to about 50 nm, about 5 nm to about 40 nm, about 5 nm to about 30 nm, or about 5 nm to about 20 nm, and in an embodiment, the thin film pattern may be formed to have a width of less than or equal to about 20 nm, similar to that of the photoresist pattern 102b.

Hereinafter, the present disclosure will be described in more detail through examples relating to the synthesis of the aforementioned polymer and the preparation of a photoresist topcoat composition including the same. However, the present disclosure is not technically limited by the following examples.

### Synthesis Example

### Synthesis of Polymer

### Synthesis Example 1: Synthesis of Compound 1a

20 g of hexafluoro-2,3-bis (trifluoromethyl)-2,3-butanediol (perfluoropinacol), 7.79 g of 2-(hydroxyethyl) methacrylate, and 18.84 g of triphenylphosphine (PH₃P) were mixed in 110 mL of diethylether under a nitrogen atmosphere and then, stirred. After the stirring for 30 minutes, the mixture was cooled down to 0° C., and another mixture of 14.52 g (71.84 mmol) of diisopropyl azodicarboxylate (DIAD) and 35 mL of diethylether was slowly added thereto over 2 hours. Subsequently, the obtained mixture was stirred at room temperature (23° C.) for 24 hours and then, concentrated.

The concentrated mixture was dissolved in dichloromethane and then, treated through column chromatography by using silica gel to separate a synthesized material. The separated material was distilled under a reduced pressure, obtaining 2-[3,3,3-trifluoro-2-hydroxy-1,1,2-tris(trifluoromethyl)propoxy]ethyl 2-methyl-2-propenoate represented by Chemical Formula 1a.
* ¹H-NMR (Acetone-d6): δ1.90 (3H, t), 4.36 (4H, m), 5.63 (1H, t), 6.09 (1H, t), 8.34 (1H,s)
* ¹⁹F-NMR (Acetone-d6): δ-70.12 (6F, m), −65.38 (6F, m)

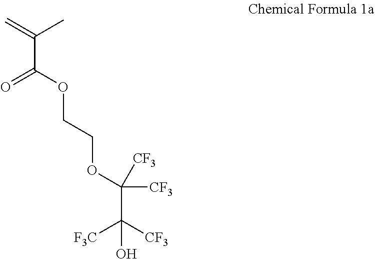 [SMILES: C=C(C)C(=O)OCCOC(C(F)(F)F)(C(F)(F)F)C(O)(C(F)(F)F)C(F)(F)F]

### Synthesis Example 2: Synthesis of Compound 1d

4.0 g of 2-aminoethyl metharcylate hydrochloride (516155, Sigma-Aldrich Co., Ltd.), 3.9 g of 1H-pyrazole-1-carboxamidine hydrochloride (402516, Sigma-Aldrich Co., Ltd.), and 130 g of anhydrous ethanol were added to a 250 mL 2-neck round bottom flask under a nitrogen atmosphere, and 13 mL of diisopropylethylamine (D125806, Sigma-Aldrich Co., Ltd.) was added thereto and then, mixed. This reactant was heated to 60° C. and then, stirred for 24 hours. Subsequently, the resultant was cooled to room temperature, and after filtering out the residue, the solvent was removed under a reduced pressure. A product therefrom was purified through column chromatography (EtOH/EtOAc= 1/1) and recrystallized (EtOAc) to obtain Compound 1d. (ref. Polym. Chem., 2020,11, 4213-4220, the entire disclosure of which is incorporated herein by reference)
* ¹H-NMR (D20): δ5.70 (1H, s), 5.44 (1H, s), 3.68 (2H, m), 3.38 (2H, m), 1.91 (3H,s)

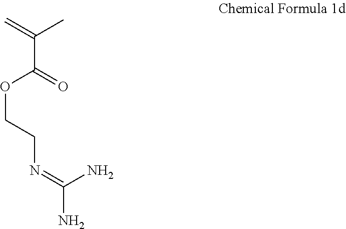

### Synthesis Example 3: Preparation of Polymer R1

17.7 g of a compound represented by Chemical Formula 1a, 3.8 g of a compound represented by Chemical Formula 1b (AG029J52, Angene), and 90 g of diisoamyl ether (DIAE) were added to a 250 mL 2-neck round bottom flask under a nitrogen atmosphere and then, heated to 85° C. When the internal temperature reached 85° C., 16 g of a 25 wt % V-601/DIAE solution (V-601 3.7 g) was slowly added thereto to react the reaction mixture for 6 hours, and the reaction mixture was cooled to room temperature and concentrated to have a solid content (e.g., amount) of 50%.

After adding 250 g of heptane to the concentrated solution, a polymer therefrom was filtered. 34 g of the filtered polymer was completely dissolved in DIAE, and 250 g of heptane was added thereto for precipitation, which were repeated twice to obtain precipitates, and then, the precipitates were completely dried to obtain a polymer having a structure of Chemical Formula 1-1 (R1, Mw=4100, a:b=90:10).

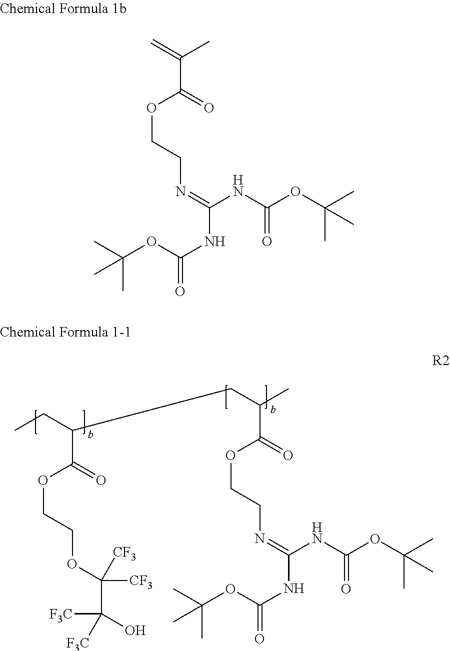

### Synthesis Example 4: Preparation of Polymer R2

17.7 g of a compound represented by Chemical Formula 1a, 3.8 g of compound represented by Chemical Formula 1b, and 1.9 g of a compound represented by Chemical Formula Chemical Formula 1c (DIVPA, Songwon), and 90 g of diisoamyl ether (DIAE) were added to a 250 mL 2-neck round bottom flask under a nitrogen atmosphere and then, heated to an internal temperature of 115° C. When the internal temperature reached 115° C., 16.0 g of a 25 wt % V-601/DIAE solution (6.6 g of V-601) was slowly added thereto, and after 6 hours, the reaction solution was cooled to room temperature and concentrated to have a solid content (e.g., amount) of 50%. After adding 270 g of heptane to the concentrated solution, a polymer produced therein was filtered. The filtered polymer was completely dissolved in 34 g of DIAE, and 270 g of heptane was added thereto for precipitation, which were repeated twice to obtain precipitates, and the precipitates were completely dried, preparing a final polymer having a structure of Chemical Formula 1-2 (R2, Mw=3,900, a:b:c=83:10:7).

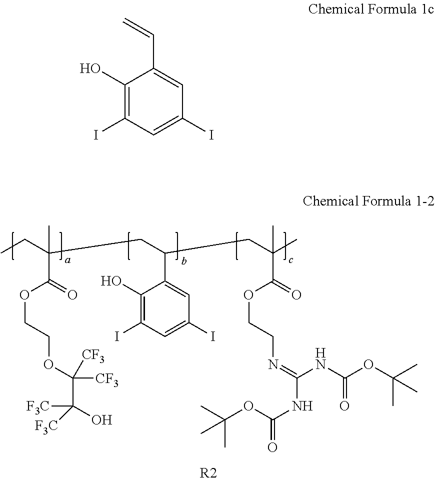

### Synthesis Example 5: Preparation of Polymer R3

A polymer having a structure of Chemical Formula 1-3 (R3, Mw=5,500, a:b=87:13) was prepared in substantially the same manner as in Synthesis Example 3 except that 1.8 g of a compound represented by Chemical Formula 1d was used instead of the compound represented by Chemical Formula 1b.

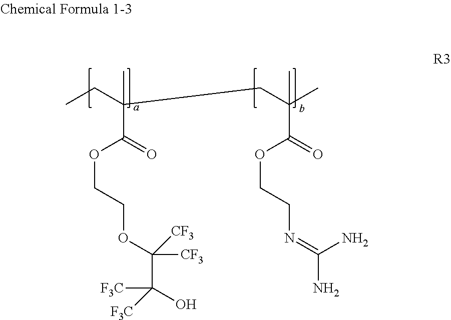

### Synthesis Example 6: Preparation of Polymer R4

A polymer having a structure of Chemical Formula 1-4 (R4, Mw=5,000, n=100) was prepared in substantially the same manner as in Synthesis Example 3 except that the compound represented by Chemical Formula 1b was not used.

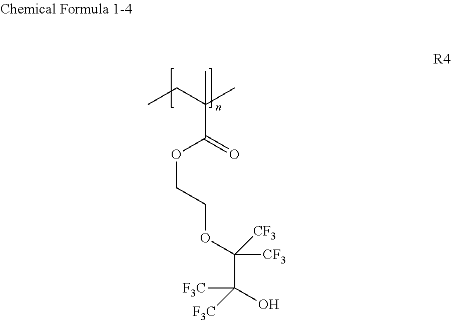

### Preparation of Resist Topcoat Compositions

### Example 1

0.98 g (0.5 wt %) of Polymer R1 according to Synthesis Example 3 was dissolved in 199 g of a mixed solvent of DIAE/PGME (w/w=97/3) and then, stirred at room temperature (23° C.) for 24 hours and filtered with a TEFLON (tetrafluoroethylene) filter having a pore size of 0.45 μm to prepare a resist topcoat composition. That is, 0.98 g (0.5 wt %) of Polymer R1, prepared according to Synthesis Example 3, was weighed and dissolved in 199 g of a mixed solvent composed of diisoamyl ether (DIAE) and propylene glycol monomethyl ether (PGME) in a weight ratio of 97:3. The mixture was stirred continuously at room temperature (23° C.) for 24 hours to ensure complete dissolution of the polymer. After stirring, the solution was filtered using a TEFLON (tetrafluoroethylene) filter with a pore size of 0.45 μm to remove any undissolved particles or impurities. The resulting clear solution was collected as the resist topcoat composition, for further application in photolithographic processes.

### Example 2, Comparative Example 1, and Comparative Example 2

Each resist topcoat composition was prepared in substantially the same manner as in Example 1, except that the polymer was changed as shown in Table 1.

### Evaluation 1: Solubility Evaluation

Each of the compositions according to Examples 1 to 2 and Comparative Examples 1 to 2 was stirred for 24 hours and examined with respect to presence or absence of precipitates with naked eyes, and the results are shown in Table 1. (absence of precipitation—solubility ○, presence of precipitation—solubility X)

### Evaluation 2: Developability Evaluation

Each of the photoresist topcoat compositions prepared in Examples and Comparative Examples was spin-coated on a silicon substrate and heat-treated at 110° C. on a hot plate for 1 minute, to form an about 5 nm-thick photoresist topcoat. The substrate with a topcoat formed thereon was rinsed with 2.38% tetramethylammonium hydroxide aqueous solution and heat-treated again at 110° C. on the hot plate for 1 minute and then, measured with respect to a thickness change of the topcoat layer, and the results are shown in Table 1.
* Residual film after development (%)=[Topcoat thickness before development (nm)—Topcoat thickness after development (nm)]×100/Topcoat thickness before development (nm)
(Residual film after development≤20%—Developability O, Residual film after development>20%—Developability X)

### Evaluation 3: Evaluation of Sensitivity and LWR

After forming a resist underlayer (thickness: 50 Å) and a photoresist thin film for EUV (thickness: 700 Å) on a 12-inch silicon substrate, each of the photoresist topcoat compositions according to the Examples and the Comparative Examples was spin-coated thereon and then, heat-treated at 110° C. for 1 minute on a hot plate to form an about 5 nm-thick photoresist topcoat.

On the wafer on which the photoresist topcoat was formed, a line was formed in the Focus-Energy Matrix (FEM) format using E-Beam equipment (JEOL JBX-9300FS). The optimal or suitable sensitivity capable of forming a Critical Dimension (CD) of 50 nm was confirmed using the interpolation method, and the results are shown in Table 1.

After confirming the optimal or suitable sensitivity, the line width roughness (LWR) dispersion was measured in the corresponding energy shot using Hitatchi's CD-SEM equipment. In order to increase the reliability of the dispersion value, the same pattern of 500 points was measured within the shot, and the final average value is shown in Table 1.

TABLE 1

| | | | | sensitivity | LWR |
|---|---|---|---|---|---|
| | polymer | solubility | developability | (μC/cm²) | (nm) |
| Example 1 | R1 | ∘ | ∘ | 1050 | 3.9 |
| Example 2 | R2 | ∘ | ∘ | 980 | 3.8 |
| Comparative | R3 | ∘ | ∘ | 1100 | 4.1 |
| Example 1 | | | | | |
| Comparative | R4 | ∘ | ∘ | 1200 | 4.3 |
| Example 2 | | | | | |

Referring to Table 1, when the resist topcoat composition according to one or more embodiments was applied, enhanced (e.g., excellent or suitable) solubility and developability were not only maintained, but also sensitivity was improved, and in addition, there was an excellent or suitable LWR improvement effect by suppressing or reducing pattern degradation. For example, when the resist topcoat composition according to one or more embodiments was applied, enhanced solubility and developability were not only maintained, but sensitivity was also improved. Additionally, there was a significant improvement in LWR (line width roughness) by suppressing or reducing pattern degradation.

In contrast, the resist topcoat compositions according to the comparative examples exhibited deteriorated sensitivity as well as no LWR improvement effect.

Throughout the disclosure, the expression “at least one of a, b and c”, “at least one of a, b or c”, “at least one selected from a, b, and c”, “at least one selected from the group consisting of a, b, and c”, “at least one from among a, b, and c”, “at least one of a to c”, etc., indicates only a, only b, only c, both a and b, both a and c, both b and c, all of a, b, and c, or variations thereof. Additionally, expressions such as “at least one of,” “one of,” and “selected from,” when preceding a list of elements, modify the entire list and not the individual elements. For example, “at least one selected from among a, b, and c,” “at least one of a, b, or c,” and “at least one of a, b, and/or c” may indicate only a, only b, only c, both a and b, both a and c, both b and c, or all of a, b, and c, or variations thereof. Furthermore, “one of a, b, and c” or “at least one of a, b, and c” supports “one of a, b, or c” or “at least one of a, b, or c”.

As used herein, the terms “use,” “using,” and “used” may be considered synonymous with the terms “utilize,” “utilizing,” and “utilized,” respectively. The use of “may” when describing embodiments of the inventive concept refers to “one or more embodiments of the inventive concept.”

As used herein, the term “about,” and similar terms are used as terms of approximation and not as terms of degree, and are intended to account for the inherent deviations in measured or calculated values that would be recognized by those of ordinary skill in the art. “About” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Also, any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

Here, unless otherwise defined, the listing of steps, tasks, or acts in a particular order should not necessarily means that the invention or claims require that particular order. That is, the general rule that unless the steps, tasks, or acts of a method (e.g., a method claim) actually recite an order, the steps, tasks, or acts should not be construed to require one.

A coating device, a device for forming patterns, an electronic apparatus/device, a manufacturing apparatus thereof, or any other relevant apparatuses/devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

In the present disclosure, each suitable feature of the various embodiments of the disclosure may be combined or combined with each other, partially or entirely, and may be technically interlocked and operated in various suitable ways, and each embodiment may be implemented independently of each other or in conjunction with each other in any suitable manner unless otherwise stated or implied.

Hereinbefore, the certain embodiments have been described and illustrated, however, it is apparent to a person with ordinary skill in the art that the present disclosure is not limited to the embodiments as described, and may be variously modified and transformed without departing from the spirit and scope of the present disclosure. Accordingly, the modified or transformed embodiments as such may not be understood separately from the technical ideas and aspects of the present disclosure, and the modified embodiments are within the scope of the claims of the present disclosure, and equivalents thereof.

### REFERENCE NUMERALS

1: forming a photoresist layer
2: forming a photoresist topcoat
3: exposing and developing the photoresist layer and the photoresist topcoat to form a resist pattern
30: photoresist topcoat
100: substrate
101: photoresist layer
102b: photoresist pattern

1 what is claimed is:

1. A resist topcoat composition, comprising:
a polymer comprising a first structural unit represented by Chemical Formula M-1 and a second structural unit represented by Chemical Formula 2; and
a solvent: 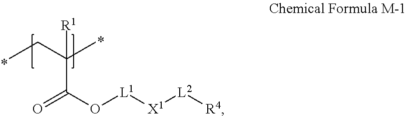
wherein, in Chemical Formula M-1,
R¹ is hydrogen or a substituted or unsubstituted C1 to C10 alkyl group,
L¹ and L² are each independently a single bond, a substituted or unsubstituted C1 to C10 alkylene group, or a combination thereof,
X¹ is a single bond; —O—; —S—; —S(═O)—; —S(═O)₂—; —C(═O)—; —C(═O)O—; —OC(═O); —OC(═O)O—; —NR^{a}—wherein R^{a} is hydrogen, deuterium, or a substituted or unsubstituted C1 to C10 alkyl group; or a combination thereof,
R⁴ is hydrogen, fluorine, a hydroxyl group, a substituted or unsubstituted C1 to C20 alkyl group, or a combination thereof,
at least one of R⁴, L¹, or L² comprises fluorine and a hydroxyl group, and
* is a linking point; and 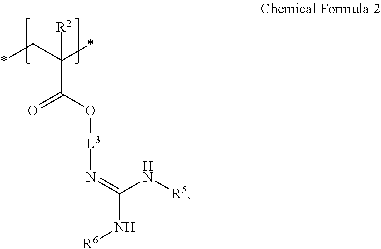
wherein, in Chemical Formula 2,
R² is hydrogen or a substituted or unsubstituted C1 to C10 alkyl group,
L³ is a single bond, a substituted or unsubstituted C1 to C10 alkylene group, or a combination thereof,
R⁵ and R⁶ are each independently hydrogen, a substituted or unsubstituted C1 to C10 alkyl group, or —C(═O)OR⁷ wherein R⁷ is a substituted or unsubstituted C1 to C10 alkyl group,
at least one of R⁵ or R⁶ is a substituted or unsubstituted C1 to C10 alkyl group, or —C(═O)OR⁷, and
* is a linking point.

2. The resist topcoat composition as claimed in claim 1, wherein the first structural unit is represented by Chemical Formula 1: 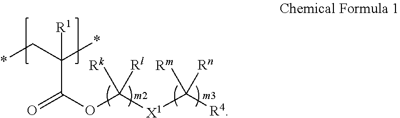
wherein, in Chemical Formula 1,
R¹ is hydrogen or a substituted or unsubstituted C1 to C10 alkyl group,
R^{k}, R^{l}, R^{m}, and Rⁿ are each independently hydrogen, fluorine, a hydroxyl group, a substituted or unsubstituted C1 to C20 alkyl group, or a combination thereof,
m2 and m3 are each independently an integer selected from 1 to 10,
X¹ is a single bond; —O—;—S—;—S(═O)—; —S(═O)₂—; —C(═O)—; —C(═O)O—; —OC(═O)—; —OC(═O)O—; —NR^{a}—wherein R^{a} is hydrogen, deuterium, or a substituted or unsubstituted C1 to C10 alkyl group; or a combination thereof,
R⁴ is hydrogen, fluorine, a hydroxy group, a substituted or unsubstituted C1 to C20 alkyl group, or a combination thereof, and at least one of R^{k}, R^{l}, R^{m}, Rⁿ, or R⁴ comprises fluorine and a hydroxyl group.

3. The resist topcoat composition as claimed in claim 1, wherein the first structural unit is any one selected from among structures of Group I: 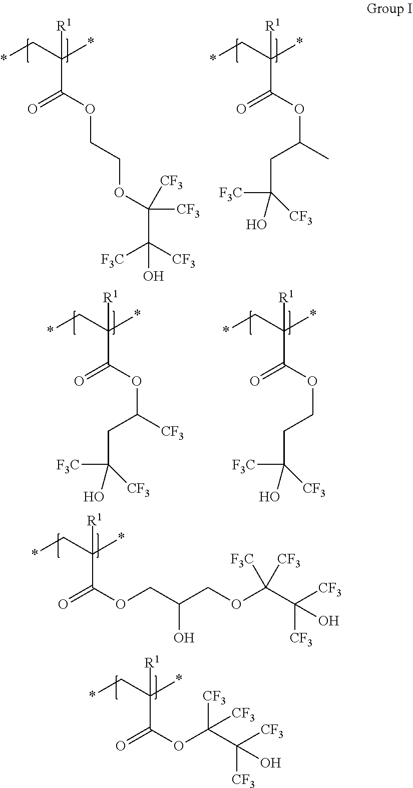
wherein, in Group I,
R¹ is each independently hydrogen or a methyl group, and
* is a linking point.

4. The resist topcoat composition as claimed in claim 1, wherein at least one of R⁵ or R⁶ is a substituted C1 to C10 alkyl group or —C(═O)OR⁷, R⁷ being a substituted C1 to C10 alkyl group.

5. The resist topcoat composition as claimed in claim 1, wherein at least one of R⁵ or R⁶ is a substituted or unsubstituted tert-butyl group or —C(═O)OR⁷, R⁷ being a substituted or unsubstituted tert-butyl group.

6. The resist topcoat composition as claimed in claim 1, wherein the polymer further comprises a structural unit represented by Chemical Formula M-2: 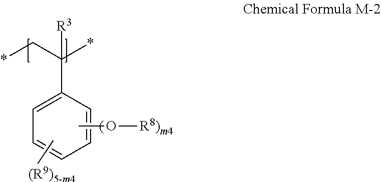
wherein, in Chemical Formula M-2,
R³ is hydrogen or a substituted or unsubstituted C1 to C10 alkyl group,
R⁸ is hydrogen or —C(═O)R^{d},
R^{d} is a substituted or unsubstituted C1 to C10 alkyl group,
R⁹ is hydrogen, a halogen, a hydroxy group, a substituted or unsubstituted C1 to C10 alkyl group, or a combination thereof,
m4 is an integer selected from 1 to 4, and
* is a linking point.

7. The resist topcoat composition as claimed in claim 6, wherein the structural unit represented by Chemical Formula M-2 is represented by any one of Chemical Formulas 4-1 to 4-4: 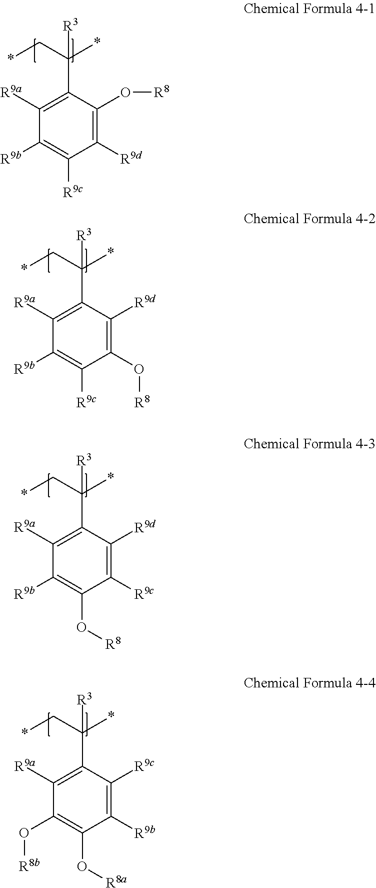
and
wherein, in Chemical Formulas 4-1 to 4-4,
R³ is hydrogen or a methyl group,
R⁸, R^{8a}, and R^{8b} are each independently hydrogen or —C(═O)R^{d},
R^{d} is a substituted or unsubstituted C1 to C5 alkyl group,
R^{9a}, R^{9b}, R^{9c}, and R^{9d} are each independently hydrogen, a halogen, a hydroxy group, a substituted or unsubstituted C1 to C10 alkyl group, or a combination thereof, and
* is a linking point.

8. The resist topcoat composition as claimed in claim 6, wherein the structural unit represented by Chemical Formula M-2 is any one selected from among structures in Group III: 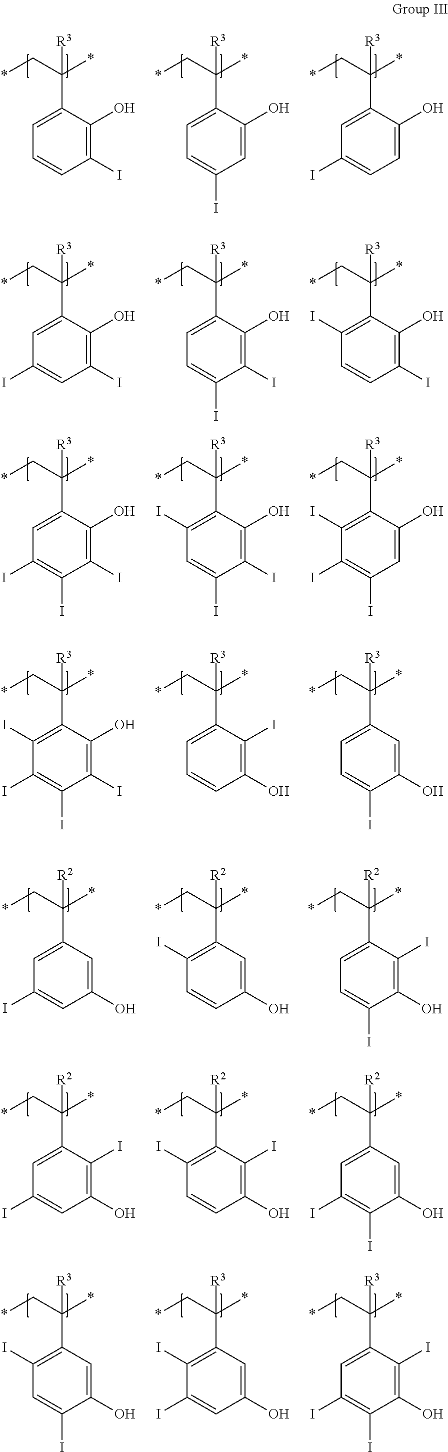 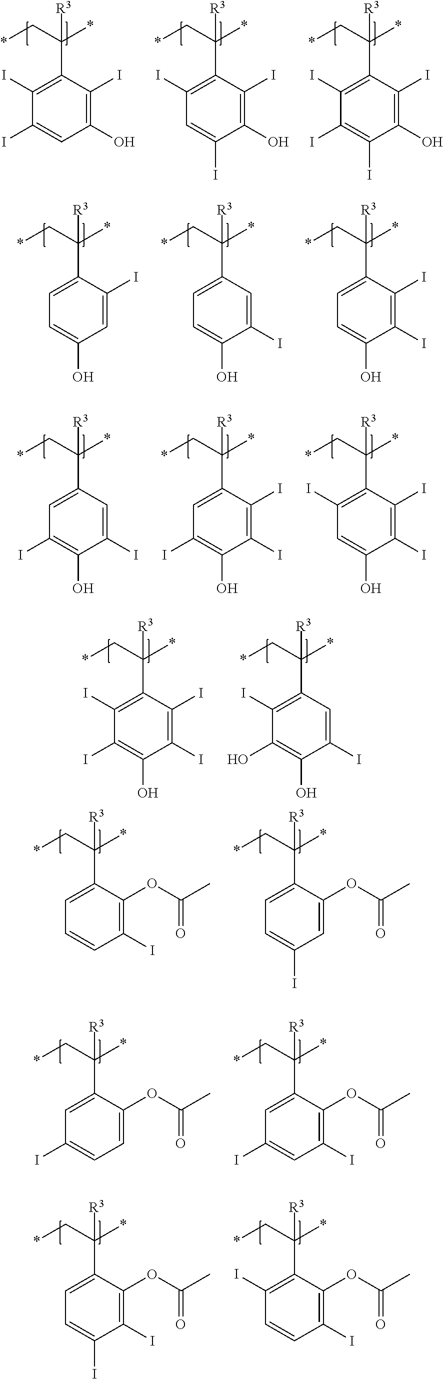 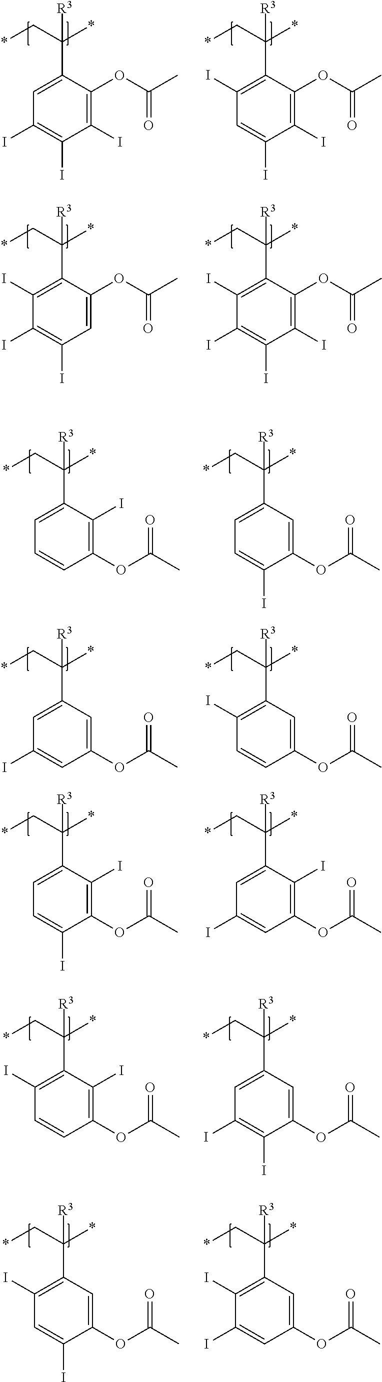 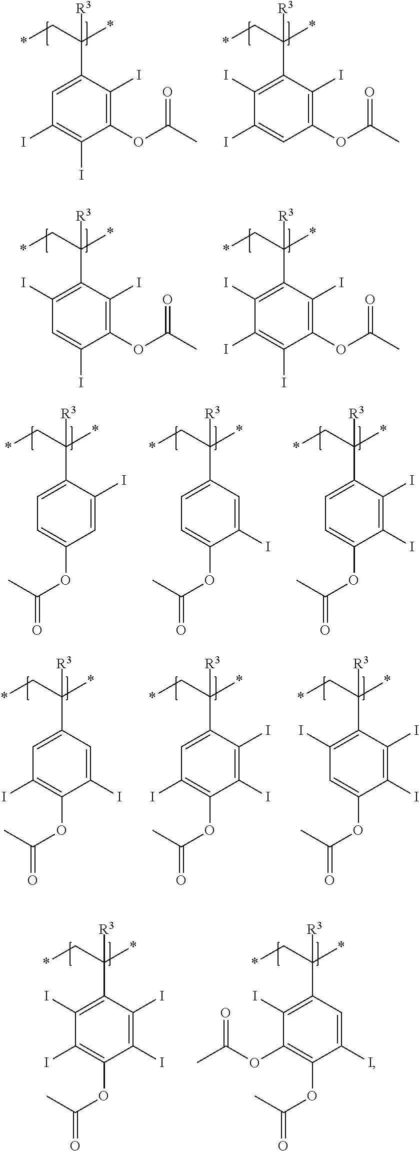
wherein, in Group III,
R³ is each independently hydrogen or a methyl group, and
* is a linking point.

9. The resist topcoat composition as claimed in claim 1, wherein the polymer comprises 50 mol % to 99 mol % of the first structural unit and 1 mol % to 50 mol % of the second structural unit, based on a total 100 mol % of the structural units of the polymer.

10. The resist topcoat composition as claimed in claim 6, wherein the polymer has a weight average molecular weight of 1,000 g/mol to 50,000 g/mol.

11. The resist topcoat composition as claimed in claim 6, wherein the polymer is 0.1 wt % to 10 wt % in amount based on a total weight 100 wt % of the resist topcoat composition.

12. The resist topcoat composition as claimed in claim 1, wherein the solvent is an ether-based solvent.

13. A method comprising
coating and heating a photoresist composition on a substrate to form a photoresist layer,
coating and heating the resist topcoat composition as claimed in claim 1 on the photoresist layer to form a topcoat, and
exposing and developing the topcoat and the photoresist layer to form a resist pattern,
wherein the method is a method of forming patterns.
